(19) United States
(12) Patent Application Publication
(10) Pub. No.: US 2026/0257927 A1
(43) Pub. Date: Sep. 3, 2026

(54) METHOD FOR COMPREHENSIVE UTILIZATION OF ULEXITE ORE RESOURCES

(71) Applicant: FUJIAN JUNGIE NEW MATERIAL TECHNOLOGY CO., LTD., Ningde (CN)

(72) Inventors: Xiaoyu YIN, Ningde (CN); Youfeng HUANG, Ningde (CN); Yue CAI, Ningde (CN)

(21) Appl. No.: 19/653,005

(22) Filed: Apr. 20, 2026

Related U.S. Application Data
(63) Continuation of application No. PCT/CN2024/071110, filed on Jan. 8, 2024.

(30) Foreign Application Priority Data
Dec. 12, 2023 (CN) 202311701501.8

(51) Int. Cl. C01B 35/10; C01D 9/04; C01D 9/16; C01F 11/46; C22B 3/06; C22B 3/22; C22B 26/10; C22B 26/20

(52) U.S. Cl. CPC C01B 35/1063; C01B 35/109; C01D 9/04; C01D 9/16; C01F 11/468; C22B 3/065; C22B 3/22; C22B 26/10; C22B 26/20; C01P 2004/20

(57) ABSTRACT

A method for comprehensive utilization of ulexite ore resources is provided, in which a ulexite ore is washed with water, mixed with water and nitric acid and reacted to obtain a slurry; the slurry is filtered, and the resultant filtrate is added with nitric acid, cooled and filtered to obtain a boric acid crystal; the resultant filtrate is reacted with a decalcifying agent and filtered, and Na⁺ and Mg²⁺ concentrations in the resultant filtrate are determined, when the Mg²⁺ concentration reaches 35 g/L or the Na⁺ concentration reaches 40 g/L, the filtrate is concentrated, crystallized and filtered; and the filtrate is used as a circulating mother liquor to replaced water for treatment of subsequent samples.

### CROSS-REFERENCE TO RELATED APPLICATIONS

This application is a continuation of International Patent Application No. PCT/CN2024/071110, filed on Jan. 8, 2024, which claims the benefit of priority from Chinese Patent Application No. 202311701501.8, filed on Dec. 12, 2023. The content of the aforementioned application, including any intervening amendments made thereto, is incorporated herein by reference in its entirety.

### TECHNICAL FIELD

This application relates to inorganic chemistry, and more particularly to a method for comprehensive utilization of ulexite ore resources.

### BACKGROUND

According to the China Boric Acid Market Forecast and Investment Strategy Report (2022 Edition) by Limu Information Consulting, global boron mining is concentrated in Turkey, the United States, Russia, South American nations and China. Leading enterprises include Eti Maden (Turkey), U.S. Borax (USA), Santa Rita (Argentina), and Quiborax (Chile). Eti Maden is the world's largest boron producer, with annual output of approximately 900,000 tons, representing 30-40% of global supply, and supplies refined products including boric acid, borax and boron oxide.

There are 63 boron mines (3 large-scale, 6 medium-scale, 54 small-scale) in China, which yield 616,500 tons of raw ore annually. Over 40 boric acid enterprises exist domestically. However, most of these enterprises are relatively small in scale, constrained by their resource endowments and production technologies. Only 10% of producers achieve capacities exceeding 50,000 tons/year. Product quality lags behind international standards, necessitating imports of high-purity boric acid. Rising demand for higher-volume and higher-grade products, and stricter requirements for resource utilization and “three wastes” management (wastewater, waste gas, solid waste) drives urgent need for advanced boric acid production technologies.

Ulexite (NaCaB₅O₆(OH)₆·5H₂O), a borate mineral, has a theoretical composition of Na₂O 7.65 wt. %, CaO 13.85 wt. %, B₂O₃ 42.95 wt. % and H₂O 35.55 wt. %. Naturally occurring as white crystalline aggregates, it dissolves readily in hot water, and partially in cold water to form a paste-like slurry upon prolonged immersion. Formed in arid regions through hydrological leaching of boron from sediments and volcanic debris, ulexite deposits occur in South America, Turkey, western USA and China's Qinghai-Tibet Plateau. It constitutes a primary ore type in Qinghai salt-lake boron resources.

The following existing literature and patents describe ulexite utilization pathways.

Wang Pei et al. produced calcium borate from natural ulexite ore powder via hydrothermal depolymerization under the conditions of 120° C., 8 h and liquid-solid ratio of 250 mL/100 g, and phase transformation by drying at about 200° C., finally yielding a product with less than 0.5 wt. % Na₂O, which satisfied industry requirements of alkali-free glass fiber (Wang Pei et al., Preparation of calcium borate from ulexite by hydrothermal depolymerization method, 2007, 39(9), 27-30). Chinese patent No. 201310309554.5 discloses a method for ulexite decomposition based on nitric acid to obtain boric acid, calcium carbonate and sodium nitrate, but lacks impurity treatment protocols, product quality specifications and scale-up engineering solutions. Chinese patent No. 201610890282.6 discloses a method for boric acid production based on ulexite but neglects comprehensive utilization of co-existing components.

Boron is not ulexite's sole valuable component. Given its complex chemistry and evolving socio-economic priorities, such as environmental protection, circular economy and resource efficiency, the integrated recovery of sodium, calcium and other constituents has become critical. Optimization of ulexite processing must therefore be dynamically specialized to site-specific ore composition and characteristics, advancing toward zero-waste, high-value resource utilization.

### SUMMARY

The present disclosure provides a method for comprehensive utilization of ulexite ore resources to address the following technical problems of (i) enabling comprehensive utilization of ulexite resources to significantly reduce the discharge of “three wastes” (i.e., waste water, waste gas and solid waste) and achieve green production; (ii) optimizing the production processes for boric acid, calcium sulfate hemihydrate whiskers and sodium nitrate product derived from ulexite ore, and realizing their optimized coupling; and (iii) addressing the engineering challenges associated with industrial scale-up required to accomplish the aforementioned objectives.

In order to address the above technical problems, the present disclosure adopts the following technical solutions.

A method for comprehensive utilization of ulexite ore resources, comprising:
(S1) pretreating a ulexite ore sample by water washing to obtain a pretreated ore, and performing a first acidolysis on the pretreated ore to obtain a first slurry, wherein the first acidolysis is performed through steps of:
mixing the pretreated ore with water at a weight ratio of 1:3-7; and adding 75-85 wt. % of a total required amount of a nitric acid solution followed by reaction at 70-85° C. for 30-60 min to obtain the first slurry, wherein the nitric acid has a weight concentration of 50%;
(S2) filtering the first slurry via a vacuum filter to obtain a first filtrate and a first filter residue; and washing the first filter residue followed by discharge;
(S3) adding the rest of the total required amount of the nitric acid solution to the first filtrate followed by a second acidolysis to obtain a second slurry; and cooling the second slurry to 10-30° C. to perform crystallization of boric acid;
(S4) filtering a cooled slurry obtained in step (S3) to obtain a boric acid crystal and a second filtrate; and washing and drying the boric acid crystal to obtain a boric acid product;
(S5) reacting the second filtrate with a decalcifying agent followed by filtration to obtain a third filtrate and a second filter residue, wherein under a first reaction condition, the second filter residue is a calcium sulfate dihydrate whisker, and under a second reaction condition, the second filter residue is a calcium sulfate hemihydrate whisker;
(S6) determining a Mg²⁺ concentration and a Na⁺ concentration in the third filtrate; when the Mg²⁺ concentration reaches 35 g/L or the Na⁺ concentration reaches 40 g/L, concentrating the third filtrate, followed by cooling crystallization and filtration to obtain a third filter residue and a fourth filtrate, wherein the third filter residue is a mixture product predominated by sodium nitrate;
(S7) discharging the mixture product obtained in step (S6) to prepare a sodium nitrate product;
(S8) when the Na⁺ concentration and the Mg²⁺ concentration in the third filtrate in step (S5) are respectively less than 40 g/L and 35 g/L, proceeding step (S9); and
(S9) repeating steps (S1-S8) to complete treatment of a next ulexite ore sample, wherein in step (S1), before addition of nitric acid, the third filtrate serves as a circulating mother liquor to replace water to be mixed with a pretreated product of the next ulexite ore sample ore in a weight ratio of 1:3-8.

In some embodiments, in step (S1), 75-80 wt. % of the total required amount of the nitric acid solution is added; and the reaction is performed at 80° C. for 48 min to obtain the first slurry.

In some embodiments, in step (S4), the boric acid crystal is subjected to three-stage countercurrent washing and dried in an oven at 60° C. for 2 h to obtain the boric acid product.

In some embodiments, in step (S5), the decalcifying agent is selected from the group consisting of sulfuric acid, a sulfate salt and a combination thereof.

In some embodiments, the sulfuric acid is a 30-98 wt. % aqueous sulfuric acid solution.

In some embodiments, in step (S7), the mixture product is a solid product containing less than 0.25 wt. % boron trioxide, and is discharged to prepare the sodium nitrate product.

In this method, the ulexite ore sample is subjected to the first acidolysis and the second acidolysis. In step (S2), the first slurry is filtered via a filtration device, such as the vacuum filter, so as to obtain the first filtrate and the first filter residue, wherein the first filter residue is subjected to countercurrent washing followed by discharge. In step (S5), the decalcifying agent is selected from the group consisting of sulfuric acid solutions with different concentrations; and the calcium sulfate dihydrate whisker is obtained at a temperature below 82° C., whereas the calcium sulfate hemihydrate whisker is obtained at a temperature ranging from 85° C. to 98° C.

In this method, in step (S7), the mixture product obtained after concentration of the third filtrate is the solid product containing less than 0.25 wt. % boron trioxide, with only a minimal amount of boron remaining in this product, resulting in a total boron utilization rate exceeding 98%. However, due to a total content of magnesium and calcium salts being approximately 3.5 wt. %, the mixture product fails to meet the quality requirements for industrial-grade sodium nitrate product (GB/T 4553). Consequently, the mixture product is discharged and processed by using conventional purification methods.

The present disclosure has the following beneficial effects.

(1) Using ulexite ore as feedstock, this disclosure employs the first acidolysis and the second acidolysis to produce boric acid product. This approach significantly lowers acidolysis temperature and simplifies liquid-solid separation of the slurry, enabling robust and scalable industrial implementation.

(2) In the technical solutions of this disclosure, the nitric acid solution is utilized for the acidolysis of ulexite ore, and the sulfuric acid serves as the decalcifying agent, having the following three critical roles. (i) It removes calcium ions from the circulating mother liquor; (ii) it generates high-value calcium sulfate whiskers (dihydrate or hemihydrate) directly as a marketable product; and (iii) it regenerates nitric acid in situ during calcium removal, substantially reducing nitric acid consumption.

(3) Lower nitric acid dosage minimizes nitrate salt formation, thereby reducing processing complexity, energy consumption, production costs and boron loss, and enhancing economic viability and resource efficiency.

(4) The mixture product obtained after concentration of the third filtrate is the solid product containing predominantly sodium nitrate, less than 0.25 wt. % B₂O₃ and approximately 3.5 wt. % total calcium and magnesium salts, resulting in the total boron utilization rate greater than 98%. This product is discharged to stabilize continuous operation, and is subsequently processed by using conventional purification methods to yield industrial-grade sodium nitrate product.

(5) Within a single coupled production system, the method sequentially yields high-purity boric acid and the calcium sulfate whisker with a purity exceeding 99%. All valuable components of ulexite ore (boron, calcium, sodium) and process reagents (sulfuric acid, nitric acid) are comprehensively utilized. By means of this, it maximizes mineral resource efficiency, while drastically reducing “three wastes” discharge (wastewater, waste gas, solid waste), fully aligning with green manufacturing principles.

### BRIEF DESCRIPTION OF THE DRAWINGS

FIG. 1 is a flow chart of a method for comprehensive utilization of ulexite ore resources according to an embodiment of this present disclosure.

### DETAILED DESCRIPTION OF EMBODIMENTS

In order to illustrate the technical solutions, objects and beneficial effects of this disclosure in detail, the present disclosure will be described in combination with the accompanying figures.

The present disclosure prioritizes comprehensive mineral resource utilization and resolves critical engineering challenges for industrial scale-up and large-scale production. A novel reaction system has been developed based on the physicochemical properties of ulexite ore. Specifically, the present disclosure employs a two-step acidolysis that significantly simplifies liquid-solid separation of post-decomposition slurry, enabling industrial implementation. Concurrently, sulfuric acid serves as a decalcifying agent, which facilitates yielding high-value calcium sulfate hemihydrate whiskers, regenerating nitric acid in situ during calcium removal, reducing nitric acid consumption and minimizing sodium nitrate by-product formation. This disclosure optimizes circulating mother liquor operation, and enhances boric acid production capacity while lowering energy consumption.

By minimizing nitric acid usage, the process ensures comprehensive utilization of all valuable components in ulexite ore (boron, calcium, sodium), substantially reducing production costs and achieving comprehensive utilization of resources.

This disclosure establishes a series of scalable process schemes to offer practical guidance for commercial-scale implementation.

As there are no quality standards for ulexite ores, it is necessary to provide targeted solutions for mineral materials with different chemical compositions.

The ulexite ore provided herein contains main components shown in Table 1, where the contents of the main components are each expressed in a unit of a weight percentage (wt. %). Moreover, the ulexite ore provided herein also contains some other components, such as crystalline water and adsorbed moisture.

TABLE 1

| | | | | | | | Total |
|---|---|---|---|---|---|---|---|
| B₂O₃ | Na₂O | CaO | Cl⁻ | MgO | SiO₂ | CO₂ | moisture |
| 25~40% | 4~8% | 10~20% | 1~4% | 1~5% | 2~10% | 1~5% | 30~35% |

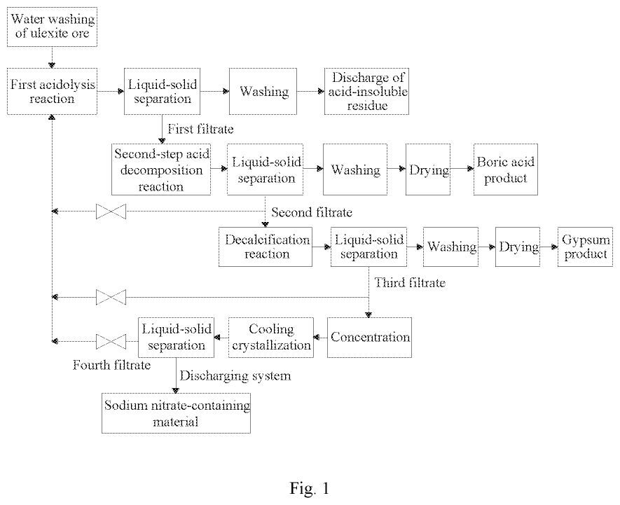

Referring to FIG. 1, the present disclosure provides a method for comprehensive utilization of ulexite resources, which is performed through the following steps.

(S1) A ulexite ore sample is washed with fresh water at a weight ratio of 1:4-8, ground, washed again, and subjected to solid-liquid separation to obtain a first filtrate and a pretreated ore. The first filtrate is treated and discharged, and the pretreated ore is dried and stored for subsequent use.

A first acidolysis is performed on the pretreated ore to obtain a first slurry, where the first acidolysis is performed through the following steps. The pretreated ore is mixed with 75-85 wt. % of a total required amount of a nitric acid solution followed by reaction at 60-80° C. for 20-40 min to obtain the first slurry, where the nitric acid solution has a solute mass concentration of 50%.

These parameter limitations optimize the acidolysis of ulexite ore, where the acidolysis of ulexite ore is performed through a first acidolysis and a second acidolysis. Initially, 75-85 wt. % of the total required amount of the nitric acid solution is added to complete the first acidolysis.

(S2) The first slurry is filtered via a filter to obtain a first filtrate and a first filter residue. The first filter residue containing less than 0.25 wt. % B₂O₃ is washed followed by discharge. The filtration is performed using a vacuum filter or other solid-liquid separation device. Stepwise acid addition facilitates solid-liquid separation of the first slurry, enabling efficient removal of acid-insoluble impurities.

(S3) The rest of the total required amount of the nitric acid solution is added to the first filtrate followed by a second acidolysis to obtain a second slurry. The second slurry is cooled to 10-30° C. to crystallization of boric acid. The cooling crystallization yields a flake-shaped boric acid crystal suitable for efficient filtration and washing. The amount of the nitric acid solution added in the first acidolysis and the second acidolysis is controlled based on a pH of the reaction system.

(S4) A cooled slurry obtained in step (S3) is filtered to obtain a second filtrate and a boric acid crystal. The boric acid crystal is washed and dried to obtain a boric acid product meeting the national standard (GB/T 538). Multi-stage countercurrent washing is employed to ensure product quality, and wash liquor is recycled into the system.

(S5) The second filtrate is reacted with a decalcifying agent followed by filtration to obtain a third filtrate and a second filter residue, where under a first reaction condition, the second filter residue is a calcium sulfate dihydrate whisker, and under a second reaction condition, the second filter residue is a calcium sulfate hemihydrate whisker. The decalcifying agent is selected from the group consisting of sulfuric acid solutions with different concentrations. An addition amount of the decalcifying agent is 90-105% of a gypsum production amount. The calcium sulfate dihydrate whisker is obtained at a temperature below 82° C., whereas the calcium sulfate hemihydrate whisker is obtained at a temperature ranging from 85° C. to 98° C.

The calcium sulfate dihydrate whisker is subjected to countercurrent washing and drying to yield a calcium sulfate whisker product. For the calcium sulfate hemihydrate whisker, both filtration and washing are performed at a temperature above 95° C.

(S6) A Mg²⁺ concentration and a Na⁺ concentration in the third filtrate are determined, respectively. When the Mg²⁺ concentration reaches 35 g/L or the Na⁺ concentration reaches 40 g/L, the third filtrate is concentrated, followed by cooling crystallization and filtration to obtain a third filter residue and a fourth filtrate, where the third filter residue is a mixture product predominated by sodium nitrate.

(S7) The mixture product obtained in step (S6) containing minor amounts of calcium and magnesium salts derived from sulfuric acid, hydrochloric acid, and boric acid is subjected to deep liquid-solid separation followed by discharge. The mixture product is subsequently purified into a sodium nitrate product using well-established industrial techniques, achieving comprehensive utilization of mineral resources.

(S8) If the Na⁺ and Mg²⁺ concentrations are respectively less than 40 g/L and 35 g/L, the third filtrate is directly fed into the next step.

(S9) The third filtrate serves as a circulating mother liquor to replace water to be mixed with a pretreated product of the next ulexite ore sample ore at a weight ratio of 1:3-8.

Countercurrent washing is implemented in all washing operations. Wash liquid is fully recycled without discharge, significantly reducing water consumption, preventing environmental pollution, and enhancing overall resource utilization efficiency.

### Embodiment 1

The present disclosure provides a method for comprehensive utilization of ulexite resources, which was performed through the following steps.

In this embodiment, the ulexite ore contains components shown in Table 2, where these components are each reported on a dry basis (expressed as in a unit of a weight percentage, wt. %). Moreover, the ulexite ore also contains some other components, such as crystalline water and adsorbed moisture.

TABLE 2

| | | | | | | | Total |
|---|---|---|---|---|---|---|---|
| B₂O₃ | Na₂O | CaO | Cl⁻ | SiO₂ | MgO | CO₂ | moisture |
| 30% | 6% | 15% | 1.5% | 5% | 2.5% | 10% | 28% |

(S101) 100 g of a ulexite ore sample was mixed with 500 g of tap water, ground, washed, subjected to pressure filtration and solid-liquid separation to obtain a first filtrate and a pretreated ore. The first filtrate was treated and discharged, and the pretreated ore was dried at 50° C. and stored for subsequent use.

(S102) The pre-treated ore was dispersed in 500 g of tap water, followed by addition of 36 g of 50 wt. % nitric acid solution. The mixture was heated to 85° C. followed by reaction for 48 min to obtain a first slurry.

The total required amount of the nitric acid solution was determined based on the stoichiometric demand to convert all calcium, magnesium, sodium, and other ions in the pretreated ore into corresponding nitrate salts, and calculated according to the actual chemical composition of the feed material. Due to complex and varying composition of natural minerals, and particularly across different mining locations where nitric acid decomposes not only boron-bearing phases to produce boric acid but also other mineral constituents, the total required amount of the nitric acid solution must be experimentally established for each ore type. For the boron ore used in this specific implementation, 46 g of 50 wt. % nitric acid was required per 100 g of boron ore.

(S103) The first slurry was filtered by vacuum filtration to obtain a first filtrate and a first filter residue. The first filter residue was subjected to three-stage countercurrent washing, dried, and discharged. The first filter residue was obtained as 3.1 g, and contained 0.13 wt. % B₂O₃.

(S104) To the first filtrate was gradually added 10 g of 50 wt. % nitric acid solution under stirring to obtain a second slurry. The second slurry was cooled to 10° C. to perform cooling crystallization.

(S105) The cooled slurry obtained in step (S104) was subjected to vacuum filtration to obtain a boric acid crystal and a second filtrate. The boric acid crystal was subjected to three-stage countercurrent washing, dried in an oven at 60° C. for 2 h, and obtained as 31 g of boric acid product.

(S106) The second filtrate was added dropwise to 83 g of 30 wt. % dilute sulfuric acid at room temperature, followed by decalcification reaction for 30 min and vacuum filtration to obtain a third filtrate and a calcium sulfate dihydrate whisker. The calcium sulfate dihydrate whisker was subjected to three-stage countercurrent washing, dried in an oven at 60° C. for 2 h, and obtained as 42 g of a calcium sulfate dihydrate whisker product with a B₂O₃ content of 0.41 wt. %.

(S107) The third filtrate was mixed with next pretreated ore, and reacted with nitric acid to perform acidolysis.

### Embodiment 2

The present disclosure provides a method for comprehensive utilization of ulexite resources, which was performed through the following steps.

(S201) 100 g of a pretreated ore was added to 500 g of the third filtrate obtained in the embodiment 1. Then, 13.6 g of 50 wt. % nitric acid solution was gradually added. The mixture was heated to 80° C. followed by reaction for 40 min to obtain a first slurry.

(S202) The first slurry was subjected to vacuum filtration to obtain a first filtrate and a first filter residue. The first filter residue was washed once, dried, and discharged. The first filter residue was obtained as 3.5 g and contained 0.11 wt. % B₂O₃.

(S203) To the first filtrate was added 3.8 g of 50 wt. % nitric acid solution under stirring to obtain a second slurry. The second slurry was cooled to 10° C. to perform cooling crystallization and precipitate a boric acid crystal.

(S204) The cooled slurry obtained in step (S203) was subjected to vacuum filtration to obtain a boric acid crystal and a second filtrate. The boric acid crystal was subjected to three-stage countercurrent washing, dried in an oven at 60° C. for 2 h, and obtained as 49 g of boric acid product.

(S205) The second filtrate was added dropwise to 80 g of 30 wt. % sulfuric acid at room temperature, followed by decalcification reaction for 30 min and filtration via a vacuum filter to obtain a third filtrate and a calcium sulfate dihydrate whisker. The calcium sulfate dihydrate whisker was subjected to three-stage countercurrent washing, dried in an oven at 60° C. for 2 h, and obtained as 42.2 g of calcium sulfate dihydrate whisker product with a B₂O₃ content of 0.048 wt. %.

(S206) The third filtrate was subjected to acidolysis with next pretreated ore.

### Embodiment 3

The present disclosure provides a method for comprehensive utilization of ulexite resources, which was performed through the following steps.

(S301) 100 g of a pretreated ore was added to the third filtrate obtained in the embodiment 2. Then, 13.6 g of 50 wt. % nitric acid solution was gradually added. The mixture was heated to 80° C. followed by reaction for 60 min to obtain a first slurry.

(S302) The first slurry was subjected to vacuum filtration to obtain a first filtrate and a first filter residue. The first filter residue was washed once, dried, and discharged. The first filter residue was obtained as 3.6 g and contained 0.098 wt. % B₂O₃.

(S303) To the first filtrate was added 3.8 g of 50 wt. % nitric acid solution under stirring to obtain a second slurry. The second slurry was cooled to 10° C. to perform cooling crystallization and precipitate a boric acid crystal.

(S304) The cooled slurry obtained in step (S303) was subjected to vacuum filtration to obtain a boric acid crystal and a second filtrate. The boric acid crystal was subjected to three-stage countercurrent washing, dried in an oven at 60° C. for 2 h, and obtained as 52 g of boric acid product with a B₂O₃ content of 56.1 wt. %.

(S305) The second filtrate was added dropwise to 88.8 g of 30 wt. % sulfuric acid at room temperature, followed by decalcification reaction at 90-95° C. for 30 min to obtain a third slurry.

(S306) The third slurry was filtered using a vacuum filter to obtain a third filtrate and a calcium sulfate hemihydrate whisker. The calcium sulfate hemihydrate whisker was subjected to three-stage countercurrent washing, dried in an oven at 60° C. for 2 h, and obtained a calcium sulfate hemihydrate whisker product with a B₂O₃ content of 0.052 wt. %.

(S307) The third filtrate was subjected to acidolysis with next pretreated ore.

### Purification of the Circulating Mother Liquor

(S401) In the aforementioned embodiments, the third filtrate was continuously recycled for acidolysis with next pretreated ore. To ensure the quality of the boric acid product, whenever the Mg²⁺ concentration in the second filtrate reached 35 g/L or the Na⁺ concentration in the second filtrate reached 40 g/L, the second filtrate was heated to 90-95° C., and a saturated sodium sulfate solution was added in a stoichiometric amount to produce the calcium sulfate hemihydrate whisker.

(S402) The third filtrate containing the whisker was concentrated to 50% of its original volume, subjected to cooling crystallization, and filtered to obtain a fourth filtrate and a white dried solid weighing 4.3 g. The composition of the solid was presented in Table 3 (expressed in a unit of wt. %).

TABLE 3

| | | | | | | | Total |
|---|---|---|---|---|---|---|---|
| Ca | SO₄²⁻ | MgO | B₂O₃ | Na | Cl⁻ | NO₃⁻ | moisture |
| 1.38 | 1.18 | 0.18 | 0.93 | 23.45 | 0.67 | 61.95 | 9 |

(S403) The fourth filtrate was subjected to acidolysis with next pretreated ore and was recycled within the process.

In the aforementioned comprehensive utilization method for ulexite ore resources, throughout the entire boron ore processing procedure, no waste water was discharged except for the waste water generated during ambient-temperature washing of the ore with fresh water in step (S1) to remove sodium chloride (NaCl), and the waste water was treated to meet discharge standards before discharging.

B₂O₃ loss rate was calculated as (total boron discharged from the system)×100/(total boron introduced into the system). B₂O₃ loss rates for the aforementioned embodiments were presented in Table 4.

TABLE 4

| | | | | Purification of |
|---|---|---|---|---|
| | Embodi- | Embodi- | Embodi- | circulating |
| | ment 1 | ment 2 | ment 3 | mother liquor |
| B₂O₃ loss rate | 0.07% | 0.08% | 0.08% | 0.04% |

The B₂O₃ loss rate was maintained at a low level. Boron, calcium, sodium, and other valuable elements derived from the ulexite ore, together with sulfuric acid and nitric acid employed in the process, were incorporated into the final products to the greatest extent possible. Consequently, mineral resource utilization efficiency was enhanced, and emissions of the “three wastes” (waste water, waste gas, and solid waste) were significantly reduced.

The embodiments described above are not intended to limit the present disclosure. Any equivalent replacements made to the descriptions and accompanying figures of this disclosure can be directly or indirectly applied to related fields, and shall fall within the scope of the present disclosure defined by the appended claims.

What is claimed is:

1. A method for comprehensive utilization of ulexite ore resources, comprising:
(S1) pretreating a ulexite ore sample by water washing to obtain a pretreated ore, and performing a first acidolysis on the pretreated ore to obtain a first slurry, wherein the first acidolysis is performed through steps of:
mixing the pretreated ore with water at a weight ratio of 1:3-7; and adding 75-85 wt. % of a total required amount of a nitric acid solution followed by reaction at 70-85° C. for 30-60 min to obtain the first slurry, wherein the nitric acid solution has a weight concentration of 50%;
(S2) filtering the first slurry via a vacuum filter to obtain a first filtrate and a first filter residue; and washing the first filter residue followed by discharge;
(S3) adding the rest of the total required amount of the nitric acid solution to the first filtrate followed by a second acidolysis to obtain a second slurry; and cooling the second slurry to 10-30° C. to perform crystallization of boric acid;
(S4) filtering a cooled slurry obtained in step (S3) to obtain a boric acid crystal and a second filtrate; and washing and drying the boric acid crystal to obtain a boric acid product;
(S5) reacting the second filtrate with a decalcifying agent followed by filtration to obtain a third filtrate and a second filter residue, wherein under a first reaction condition, the second filter residue is a calcium sulfate dihydrate whisker, and under a second reaction condition, the second filter residue is a calcium sulfate hemihydrate whisker;
(S6) determining a Mg²⁺ concentration and a Na⁺ concentration in the third filtrate; when the Mg²⁺ concentration reaches 35 g/L or the Na⁺ concentration reaches 40 g/L, concentrating the third filtrate, followed by cooling crystallization and filtration to obtain a third filter residue and a fourth filtrate, wherein the third filter residue is a mixture product predominated by sodium nitrate;
(S7) discharging the mixture product obtained in step (S6) to prepare a sodium nitrate product;
(S8) when the Na⁺ concentration and the Mg²⁺ concentration in the third filtrate in step (S5) are respectively less than 40 g/L and 35 g/L, proceeding step (S9); and
(S9) repeating steps (S1-S8) to complete treatment of a next ulexite ore sample, wherein in step (S1), before addition of nitric acid, the third filtrate serves as a circulating mother liquor to replace water to be mixed with a pretreated product of the next ulexite ore sample ore in a weight ratio of 1:3-8.

2. The method of claim 1, wherein in step (S1), 75-80% of the total required amount of the nitric acid solution is added; and the reaction is performed at 80° C. for 48 min to obtain the first slurry.

3. The method of claim 1, wherein in step (S4), the boric acid crystal is subjected to three-stage countercurrent washing and dried in an oven at 60° C. for 2 h to obtain the boric acid product.

4. The method of claim 1, wherein in step (S5), the decalcifying agent is selected from the group consisting of sulfuric acid, a sulfate salt and a combination thereof.

5. The method of claim 4, wherein the sulfuric acid is a 30-98 wt. % aqueous sulfuric acid solution.

6. The method of claim 1, wherein in step (S7), the mixture product is a solid product containing less than 0.25 wt. % boron trioxide, and is discharged to prepare the sodium nitrate product.
